(19) United States
(12) Patent Application Publication
(10) Pub. No.: US 2025/0167059 A1
(43) Pub. Date: May 22, 2025

(54) POWER CONVERSION DEVICE

(71) Applicant: HITACHI ASTEMO, LTD., Hitachinaka-shi, Ibaraki (JP)

(72) Inventors: Junpei KUSUKAWA, Chiyoda-ku, Tokyo (JP); Eiichi IDE, Chiyoda-ku, Tokyo (JP)

(73) Assignee: HITACHI ASTEMO, LTD., Hitachinaka-shi, Ibaraki (JP)

(21) Appl. No.: 18/841,795

(22) PCT Filed: Mar. 16, 2023
(86) PCT No.: PCT/JP2023/010450

§ 371 Date: Aug. 27, 2024

(30) Foreign Application Priority Data
Jun. 15, 2022 (JP) 2022-096841

(51) Int. Cl. H01L 23/31; H01L 21/48; H01L 23/13; H01L 23/14; H01L 23/36; H01L 23/498

(52) U.S. Cl. CPC H01L 23/3107; H01L 21/4846; H01L 23/13; H01L 23/145; H01L 23/49861; H01L 23/36

(57) ABSTRACT

A power conversion device according to the present invention comprises a semiconductor device and a wiring board. The wiring board has a through-hole, and a portion of an insulating resin and a heat spreader of the semiconductor device are disposed so as to pass through the through-hole and protrude to the other side of the wiring board. The semiconductor device has a flange section. A gap between the inner circumferential surface of the through-hole and the insulating resin of the semiconductor device inside the through-hole and/or a gap between one side of the wiring board and the flange section is filled with a first resin material, and a second resin material covering at least a connection portion between an external terminal and a power wiring layer is coated onto the one side of the wiring board.

### TECHNICAL FIELD

The present invention relates to a power conversion device.

### BACKGROUND ART

In recent years, power conversion devices using power semiconductor elements have been widely used in various fields such as consumer use, automobile use, railway use, industrial use, and infrastructure use from the viewpoint of effective use of resources, promotion of energy saving, and suppression of global warming gas emission. Representative examples of the automobile use include an electric vehicle (EV), and a hybrid car (HEV) in which motor drive and engine drive are combined. In contrast to the HEV that travels by assisting driving force of the motor with driving force of the engine, the EV travels only by driving force of the motor, the driving force being purely electric force. Thus, a power conversion device capable of handling larger electric power is required for widespread use of the EV.

The power conversion device used in the EV is required to increase a cruising distance of the EV, for example, and thus a battery to be mounted needs to be increased in capacity. Increasing the capacity causes increase in size of the battery and increase in weight of the battery, so that increase in capacity with a small size and a light weight due to increase in energy density has been promoted as technology development of the battery. Increase in volume and weight of not only the battery but also the power conversion device causes deterioration in not only electric cost performance (a travelable distance per a certain electric power) of an automobile but also traveling performance that is basic performance of the automobile, such as traveling, turning, and stopping. Thus, an entire drive system including mainly the motor and the power conversion device is also required to be reduced in size and weight.

The power conversion device is mainly composed of a power semiconductor device (power module) including a power semiconductor element such as an insulated gate bipolar transistor (IGBT) or a silicon carbide-metal-oxide-semiconductor field-effect transistor (SiC-MOSFET). The power semiconductor device is an electronic component that handles high voltage and large current as compared with a normal electronic circuit. When a current is increased, loss increases in proportion to the square of the current to increase a calorific value. Reducing this heat generation requires not only conductor resistance to be reduced by increasing a volume of conductors used in the power conversion device, but also heat generation of a circuit component to be reduced by cooling while the circuit component is mounted on a printed circuit board.

For example, PTL 1 discloses a configuration of a semiconductor device in which an opening is provided in a housing to allow a heat spreader to be disposed in the opening of the housing, thereby reducing heat generation of an electronic component by cooling.

### CITATION LIST

### Patent Literature

PTL 1: JP 5898575 B2

### SUMMARY OF INVENTION

### Technical Problem

Conventional techniques have a problem to secure insulation reliability because when a structure is used in which terminals of a power module mounted in an opening part of a printed circuit board are insulated by coating of resin, the resin leaks and voids are formed during filling of the resin into a gap between the printed circuit board and the terminals. In view of this problem, an object of the present invention is to provide a power conversion device in which ensuring of insulation reliability, improvement of heat dissipation, and miniaturization coexist with each other.

### Solution to Problem

A power conversion device includes: a semiconductor device including a semiconductor element and a heat spreader that are sealed with an insulating resin, and an external terminal that protrudes from the insulating resin; and a circuit board equipped with the semiconductor device and including a power wiring layer connected to the external terminal. The circuit board includes a through-hole. The semiconductor device is disposed with the external terminal connected to the power wiring layer on one surface of the circuit board while a part of the heat spreader and the insulating resin of the semiconductor device protrude to another surface of the circuit board through the through-hole. The semiconductor device includes a flange part facing or in contact with the one surface of the circuit board and covering an opening edge of the through-hole on the one surface of the circuit board. At least one of a gap between an inner peripheral surface of the through-hole and the insulating resin of the semiconductor device in the through-hole and a gap between the one surface of the circuit board and the flange part is filled with a first resin material, and the one surface of the circuit board is coated with a second resin material covering at least a connection part between the external terminal and the power wiring layer.

### Advantageous Effects of Invention

A power conversion device in which ensuring of insulation reliability, improvement of heat dissipation, and miniaturization coexist with each other can be provided.

### BRIEF DESCRIPTION OF DRAWINGS

FIG. 1 is a plan view and a sectional view illustrating an example of a power conversion device using a conventional technique.

FIG. 2 is a diagram illustrating a first problem of a power conversion device using a conventional technique.

FIG. 3 is a diagram illustrating a second problem of a power conversion device using a conventional technique.

FIG. 4 is a diagram of a power conversion device according to an embodiment of the present invention.

FIG. 5 is a sectional view of a power semiconductor device used in the power conversion device of the present invention.

FIG. 6 is a sectional view of a printed circuit board used in the power conversion device of the present invention.

FIG. 7 is a diagram illustrating a modification of the present invention.

FIG. 8 is a diagram illustrating a manufacturing process of the power conversion device of the present invention.

FIG. 9 is a diagram illustrating a manufacturing process of a power conversion device according to a modification of the present invention.

FIG. 10 is a diagram showing partial discharge test results of the power conversion device of each of the embodiment and the modification of the present invention, and the example of conventional techniques shown in FIGS. 2 and 3.

FIG. 11 is a sectional view illustrating a configuration in which coolers are individually provided above and below the power conversion device of the present invention.

Hereinafter, embodiments of the present invention will be described with reference to the drawings. The description and drawings below are examples for describing the present invention, and are eliminated and simplified as appropriate for the sake of clarity of description. The present invention can be also implemented in various other forms. Unless otherwise specified, each component may be singular or plural.

Each drawing shows a position, a size, a shape, a range, and the like of each component that may not represent an actual position, size, shape, range, and the like to facilitate understanding of the invention. Thus, the present invention is not necessarily limited to the position, size, shape, range, and the like disclosed in each drawing.

### One Embodiment of Present Invention and General Configuration of Device

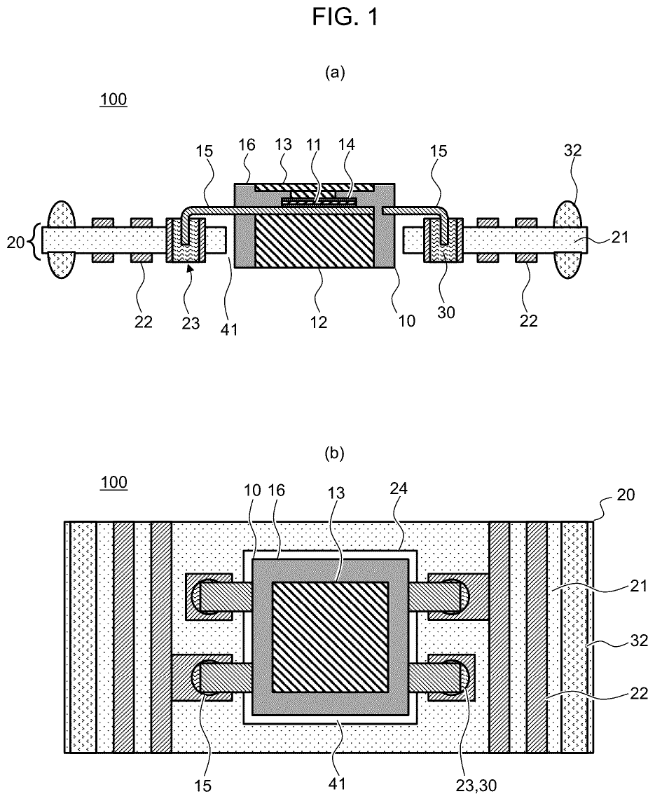

### (FIG. 1)

FIG. 1 (a) is a sectional view of a conventional power conversion device, and FIG. 1 (b) is a plan view of the conventional power conversion device from an upper viewpoint. A power conversion device 100 includes a power semiconductor device 10 (power module), a printed circuit board 20 (referred to below as a board 20), a bus bar, a capacitor, and the like. The board 20 is illustrated without a wiring layer of an inner layer by eliminating the wiring layer.

The power conversion device 100 converts a DC voltage of a battery into pseudo AC voltage by switching of the power semiconductor element 11 and drives a motor with high efficiency by the pseudo AC voltage. The power semiconductor element 11 includes an IGBT, for example. The power module generates heat by switching with a large current in the power semiconductor element 11, and the board 20, the bus bar, and the capacitor also generate heat in proportion to the product of the square of each of currents flowing through the respective components due to loss caused by an electrical resistance component of a material of corresponding one of the respective components.

The power conversion device 100 using a conventional technique includes the power semiconductor device 10 (referred to below as a semiconductor device 10) disposed on the board 20 provided with a through-hole. Between the semiconductor device 10 and the board 20, a gap 41 is formed. The semiconductor device 10 includes the power semiconductor element 11 and heat spreaders 12 and 13 that are sealed with an insulating resin 16, and an external terminal 15 protruding from the insulating resin 16. The semiconductor element 11 and the heat spreader 13 are bonded to each other with a bonding material 14. The board 20 equipped with the semiconductor device 10 is provided at its opposite ends with respective resin frames 32 made of a non-flowable resin material. The board 20 includes a power wiring layer 22 serving as a circuit conductor connected to the external terminal 15, an insulation layer 21, and a through-hole 23. The external terminal 15 is inserted into the through-hole 23 formed in the board 20, and is bonded and fixed in the through-hole 23 by filling the through-hole 23 with a bonding material 30 such as molten solder. As a result, the power wiring layer 22 of the board 20 and the semiconductor device 10 are electrically connected to each other through the external terminal 15.

The semiconductor device 10 handles a current in a range from a small current of several A to a large current of several 100 A depending on its output capacitance. In particular, the semiconductor device 10 for handling a large current of several 100 A has a width between the external terminals 15, the width increasing by several mm to several 10 mm. Miniaturizing the power conversion device 100 and the semiconductor device 10 as described above requires reduction in an insulation distance between the terminals 15 of the semiconductor device 10 and corresponding reduction in an insulation distance between wirings 22 of the board 20. The insulation distance conforms to a standard such as IEC60664-1, and a space distance and a creepage distance according to this standard are required between the external terminals 15 and between the wirings 22 without being sealed with resin. Further reduction in the insulation distance requires resin sealing for the external terminals 15 and the wirings 22.

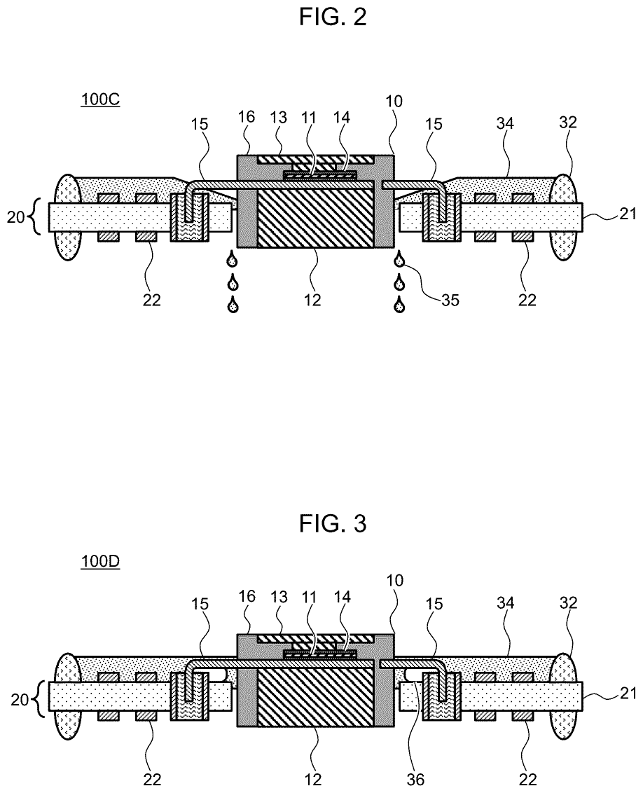

### (FIG. 2)

A problem to be solved for resin sealing performed on the semiconductor device 100 using a conventional technique will be described. A power conversion device 100C is configured by applying a resin material 34 to the board 20 and the external terminal 15 of the semiconductor device 10 in the power conversion device 100 using a conventional technique. The resin material 34 having a viscosity of 0.5 Pa·s at 25° C. is used to be applied covering the wiring layer 22 of the board 20 and the external terminal 15. Although the resin material 34 is then cured under predetermined conditions, the resin material 34 flows down from a gap between the board 20 and the semiconductor device 10 during application or curing of the resin material 34, thereby causing leakage 35 of the resin material. The resin material 34 having viscosity lower than a predetermined standard as described above causes a problem that the external terminal 15 cannot be covered with the resin material 34.

### (FIG. 3)

Another problem to be solved for resin sealing performed on the power conversion device 100 using a conventional technique will be described. Although a power conversion device 100D is configured by applying the resin material 34 to the board 20 and the external terminal 15 of the semiconductor device 10 in the power conversion device 100 using a conventional technique, the resin material 34 having a viscosity of 30 Pa·s at 25° C. higher than that in FIG. 2 is used. Although the resin material 34 is then cured under predetermined conditions, the resin material is prevented from leaking from the gap between the board 20 and the semiconductor device 10 unlike FIG. 2. However, a space (void) 36 is formed in the gap between the external terminal 15 and the board 20, the space being not filled with the resin 34.

As described above, when the void 36 is formed with the resin material 34 having viscosity higher than the predetermined standard, a high electric field is applied to the void 26 due to a relationship between relative permittivities of the resin 34 and the void 26 when a high voltage is applied between the terminals 15 and between the terminals 15 and the wirings 22. Increase of an electric field causes partial discharge in the void 26 to cause progress of partial discharge deterioration in the resin material 34, so that dielectric breakdown may occur between the terminals 15 and between the terminals 15 and the wirings 22.

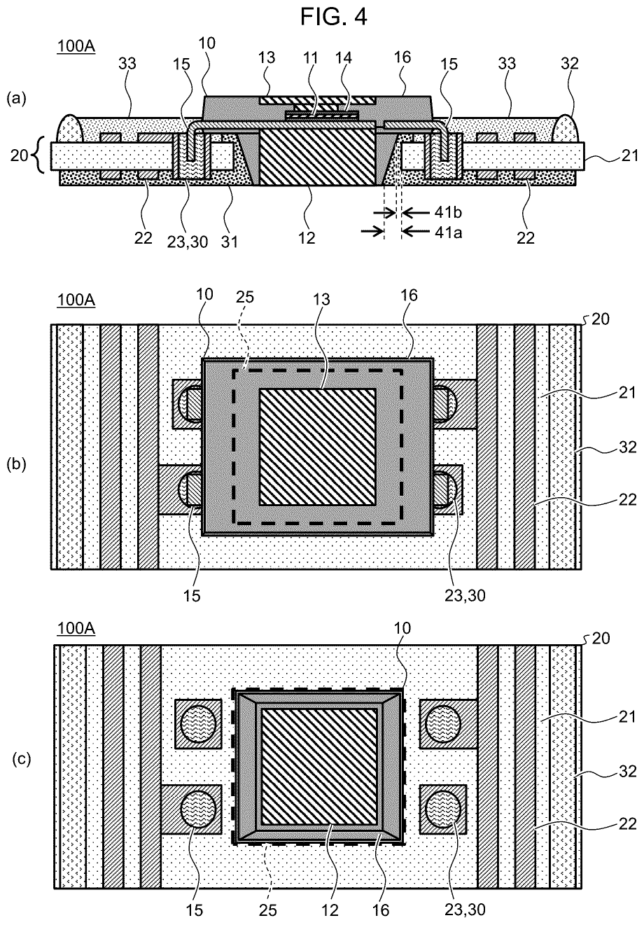

### (FIGS. 4, 5, and 6)

FIG. 4 (a) is a sectional view of the power conversion device 100A according to an embodiment of the present invention, FIG. 4 (b) is an upper plan view of the power conversion device 100A, and FIG. 4 (c) is a plan view as viewed from below. To solve the problems caused by the power conversion devices 100C and 100D using conventional techniques, the following configuration is used in the power conversion device 100A of the present invention.

The semiconductor device 10 includes: the external terminal 15 and the power wiring layer 22 that are connected to each other on one surface of the board 20; and the heat spreader 13 and the insulating resin 16 that are disposed partially passing through a through-hole 24 (FIG. 6) to protrude to the other surface of the board 20. When the heat spreader 13 is inserted into the through-hole 24 provided in the board 20, a gap is formed between the heat spreader 12 and the board 20 and includes a gap 41a increasing toward a surface of heat spreader 12 (a surface not covered with a resin material 31) and a gap 41b decreasing toward the board 20 by inclining the insulating resin 16 of the semiconductor device 10. That is, the gap between the insulating resin 16 and the through-hole 24 increases along a direction in which the insulating resin 16 of the semiconductor device 10 protrudes to the other surface of the board 20 through the through-hole 24. This structure facilitates filling of the first resin material 31, and enhances filling properties of the resin by narrowing the width toward the board 20.

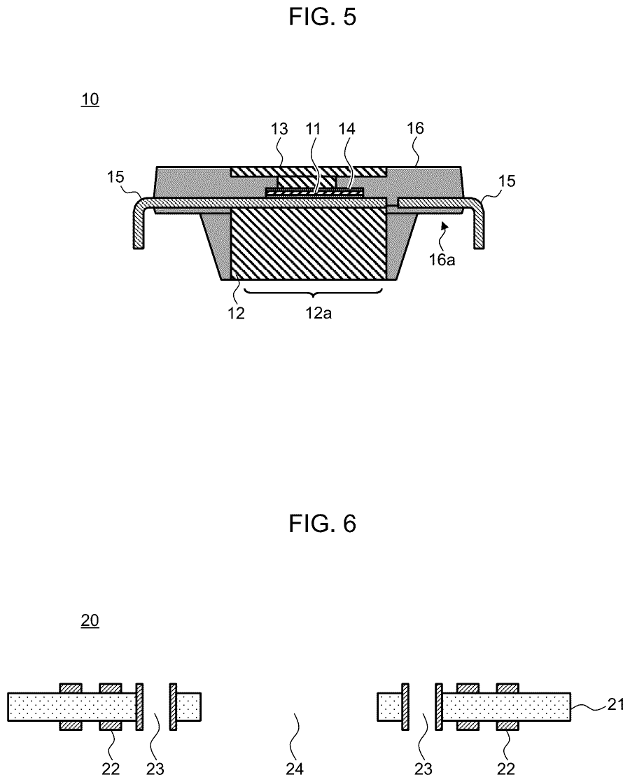

The semiconductor device 10 further includes a flange part 16a facing or in contact with the one surface of the board 20 and covering an opening edge of the through-hole 24 in the one surface of the board 20 (FIG. 5). The first resin material 31 is filled into at least one of a gap between an inner peripheral surface of the through-hole 24 and the insulating resin 16 of the semiconductor device 10 in the through-hole 24 and a gap between the one surface of the board 20 and the flange part 16a. The one surface of the board 20 is coated with a second resin material 33 to cover at least a connection part between the external terminal 15 and the power wiring layer 22.

As the second resin material 33, a resin material having higher fluidity in a molten state than the first resin material 31 is used. The board 20 includes a resin frame 32 at an end part of the surface coated with the second resin material 33 (the one surface of the board 20), and a resin material softer than a resin material used for forming the resin frame 32 and the insulating resin 16 of semiconductor device 10 is used for the first resin material 31 and the second resin material 33. Examples of the resin material having high fluidity used for the second resin material 33 include silicone and epoxy. As a result, cracks to be formed between the resin materials 31 and 33, and the board 20, and between the resin materials 31 and 33, and the insulating resin 16 of the semiconductor device, can be suppressed.

The above configuration enables providing the power conversion device 100A capable of: directly curing the resin material (second resin material 33) without causing the leakage 35 of the resin material from the gap 41 between the semiconductor device 10 and the board 20; and covering the external terminal 15 with the second resin material 33. The first resin material and the second resin material may be cured by using a method for directly leaving and curing the first resin material 31 and the second resin material 33 at room temperature (a resin material of a room temperature curing type), or using a method for curing the first resin material and the second resin material by applying heat at 120° C. (a resin material of a heat curing type).

Using a resin material having a viscosity lower than that of the first resin material 31 for the second resin material 33 enables filling even a gap provided with a wide width between the external terminal 15 and the board 20 with the resin material without generating the void 36. As a result, partial discharge can be prevented from occurring even when a high voltage is applied, and insulation reliability can be secured. When the insulation reliability is improved as described above, an insulation distance can be further reduced to enable miniaturization of the power conversion device 100A.

### Modification

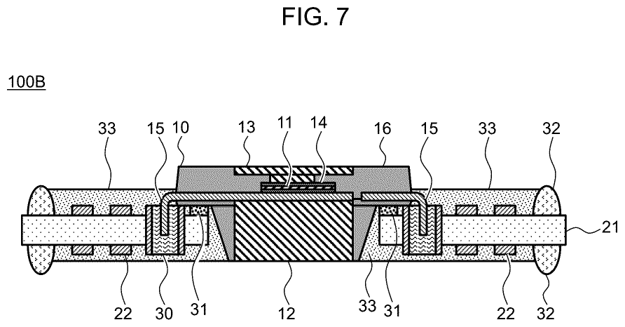

### (FIG. 7)

A power conversion device 100B according to a modification of the present invention is configured such that a first resin material 31 is formed only in a gap part between one surface of a board 20 and a flange part 16a (see FIG. 5) of a semiconductor device 10, and a second resin material 33 is used for applying a resin material to the remainder of the board 20. Even when distribution of application of the first resin material 31 and the second resin material 33 to the board 20 is changed as described above, resin leakage 35 and formation of a void 36 can be prevented.

### Method for Creating Power Conversion Device

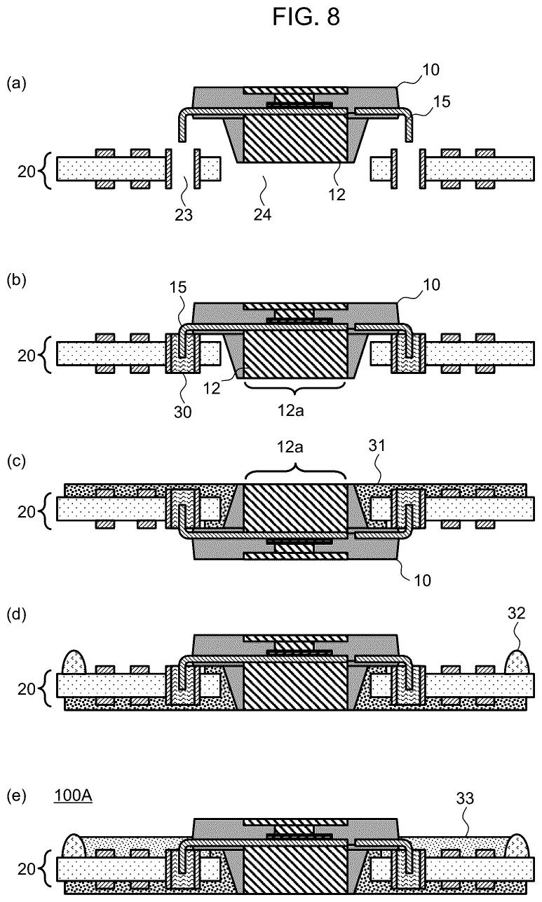

### (FIG. 8)

A method for creating the power conversion device 100A will be described with reference to FIGS. 8 (a) to 8 (e). First, a method for creating the semiconductor device 10 and the board 20 necessary for the power conversion device 100A will be described. Mounted components are described with reference to FIGS. 5 and 6 without illustrating drawings for describing respective steps.

The semiconductor device 10 is first created by bonding the power semiconductor element 11 onto the heat spreader 12 with the bonding material (solder) 14, and electrically connecting a gate electrode of the power semiconductor element 11 to the external terminal 15 using a wire (not illustrated in the drawing). Next, the heat spreader 13 is bonded to a surface of the power semiconductor element 11 with the bonding material 14, the surface being opposite to the surface bonded to the heat spreader 12. Then, the power semiconductor element 11 and the heat spreaders 12 and 13 are sealed with the insulating resin 16 by transfer molding while the heat spreaders 12 and 13 each have a surface exposed, the surface being opposite to the surface bonded to the power semiconductor element 11. Finally, the external terminal 15 is bent to complete the semiconductor device 10. The heat spreader 12 and the external terminal 15 are integrally molded using a lead frame.

Subsequently, the printed circuit board 20 with multilayers having four wiring layers is prepared. The power conversion device 100A handles a current of several 100 A, so that copper foil with a thickness of 200 μm (thicker than a copper foil generally used in an electronic device) is used for the wiring layer 22 of the board 20. The insulation layer 21 of the board 20 uses a glass fiber-reinforced epoxy resin base material. The copper foil of each wiring layer 22 of the board 20 is etched in advance to serve as a circuit of the power conversion device 100. The board 20 is completed by forming the through-hole 24 as a place where the semiconductor device 10 is disposed and the through-hole 23 into which the external terminal 15 is inserted.

Based on the semiconductor device 10 and the board 20 having been completed, a method for creating the power conversion device 100A will be described. FIG. 8 (a) illustrates the semiconductor device 10 disposed in the through-hole 24 of the board 20 to locate the heat spreader 12 on an insertion side (lower side). The external terminal 15 of the semiconductor device 10 is inserted into the through-hole 23 of the board 20. Next, FIG. 8 (b) illustrates the through-hole 23 and the external terminal 15 that are electrically connected to each other by pouring molten solder 30 into the through-hole using a flow soldering device. Subsequently, FIG. 8 (c) illustrates the semiconductor device 10 and the board 20 that are turned over to fill a gap between the semiconductor device 10 and the board 20 with the first resin material 31 having a viscosity of 30 Pa·s at 25° C., the first resin material 31 being applied covering the wiring layer 22 of the board 20 and being cured under predetermined conditions. Here, a surface (first surface 12a) of the heat spreader 12 of the semiconductor device 10, the surface protruding to the other surface of the board 20, is disposed outside the other surface of the board 20 to be prevented from being covered with the first resin material 31. As a result, the first resin material 31 or the second resin material 33 is not formed on the first surface 12a.

Next, FIG. 8 (d) illustrates the semiconductor device 10 and the board 20 that are reversed to be in the same state as in FIG. 8 (b) to form the resin frame 32 with a non-flowable resin material in an end part of a surface of the board 20, the surface being not coated with the resin material 31. Then, FIG. 8 (e) illustrates the power conversion device 100A that is completed by applying the second resin material 33 having a viscosity of 0.5 Pa·s at 25° C. to a height covering the wiring layer 22 of the board 20 and curing the resin material 33 under predetermined curing conditions. When the first resin material 31 and the second resin material 33 contain fillers different in content from each other, a similar preparation method can be performed using the same resin material. At this time, the first resin material 31 needs to have a higher viscosity than the second resin material 33, so that the first resin material 31 has a larger content of the filler than the second resin material 33. Examples of the filler include a powder component such as aluminum or silica, and the viscosity increases as the content increases.

### Method for Manufacturing Power Conversion Device of Modification

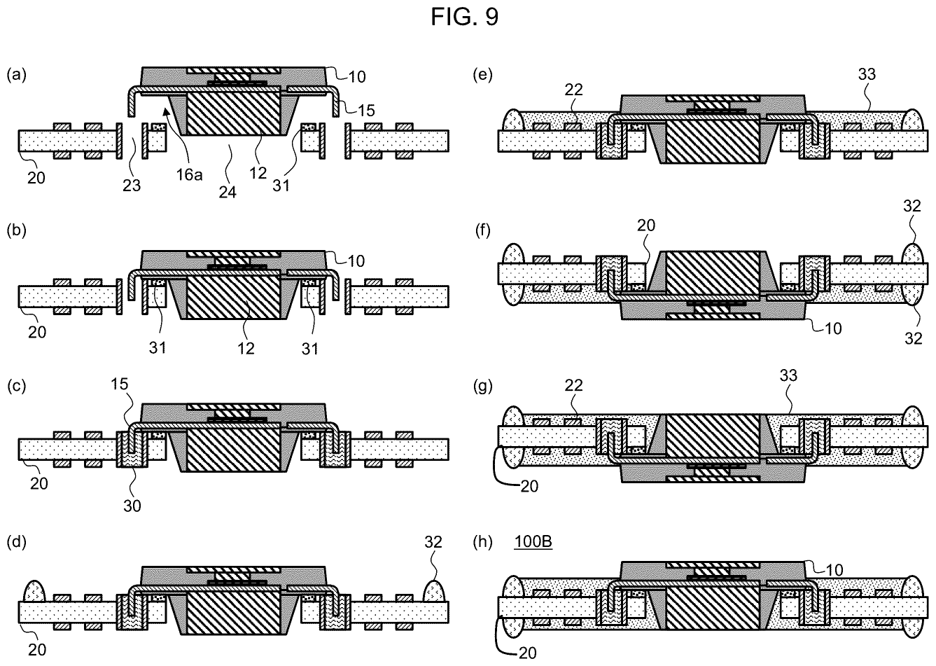

### (FIG. 9)

A method for creating the power conversion device 100B will be described with reference to FIGS. 9 (a) to 9 (h). The power conversion device 100B is similar in the method for manufacturing the semiconductor device 10 and the board 20 to that of the power conversion device 100A described in FIG. 8. FIG. 9 (a) illustrates a surface around the through-hole 24 of the board 20, the surface facing the flange part 16a of the semiconductor device 10 and being coated with the first resin material 31 having a viscosity of 100 Pa·s at 25° C. Subsequently, FIG. 9 (b) illustrates the semiconductor device 10 disposed in the through-hole 24 of the board 20 and the heat spreader 12 in its lower part located downward, the external terminal 15 of the semiconductor device 10 that is inserted into the through-hole 23 of the board 20, and the first resin material 31 cured under predetermined conditions to fix the semiconductor device 10 and the board 20 to each other and close a gap in the board 20 of the semiconductor device 10.

Next, FIG. 9 (c) illustrates the through-hole 23 and the external terminal 15 that are electrically connected to each other by pouring molten solder 30 into the through-hole 23 using a flow soldering device. FIG. 9 (d) next illustrates the resin frame 32 made of a non-flowable resin material at an end part of one surface (surface provided with the first resin material 31 and in contact with the flange part 16a of the semiconductor device 10) of the board 20. FIG. 9 (e) illustrates the second resin material 33 having a viscosity of 0.5 Pa·s at 25° C. and applied to a height covering the wiring layer 22 of the board 20, and being cured under predetermined curing conditions. FIG. 9 (f) illustrates the semiconductor device 10 and the board 20 that are reversed to form the resin frame 32 with a non-flowable resin material also in an end part of the other surface of the board 20. FIG. 8 (g) illustrates the second resin material 33 having a viscosity of 0.5 Pa·s at 25° C. and applied to a height covering the wiring layer 22 of the board 20, and being cured under predetermined curing conditions. FIG. 9 (h) illustrates the power conversion device 100B that is completed by reversing the semiconductor device 10 and the board 20 again by 180 degrees after curing the resin material 33.

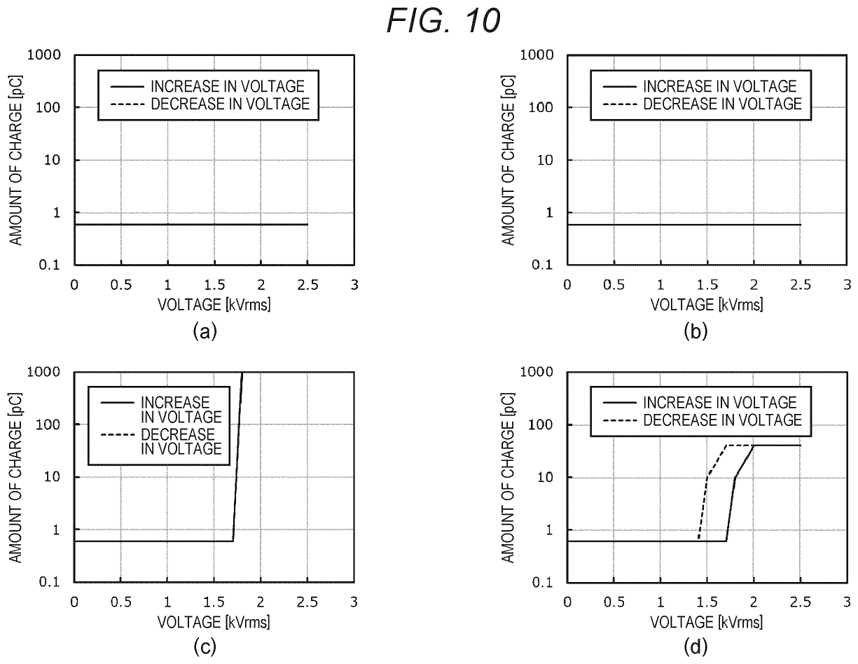

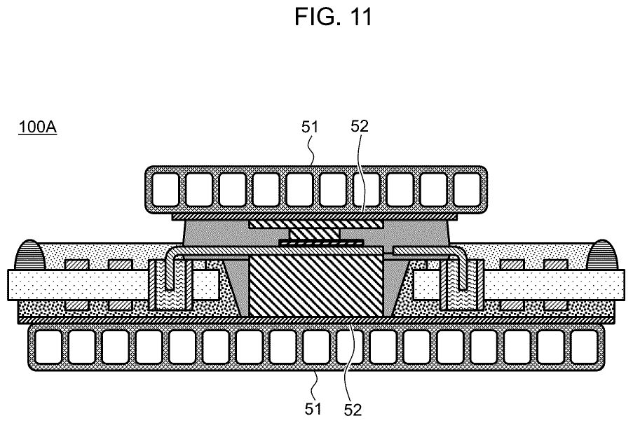

### (FIG. 10)

Results of a partial discharge test will be described below, the partial discharge test having been performed to verify effect of insulation reliability of each of the power conversion device 100A according to the present invention, the power conversion device 100B of the modification, and the power conversion devices 100C and 100D each using a conventional technique.

The partial discharge test was performed using a partial discharge measuring device that measured a voltage (partial discharge starting voltage) at which a partial discharge occurred in each sample when an AC voltage was applied between the external terminals 15 of the semiconductor device 10 and the AC voltage was gradually increased from 0 V. The external terminal 15 of the semiconductor device 10 was inserted into the through-hole 23 of the board 20 and bonded by solder, so that the voltage was also applied to the wiring 22 of the board 20. A threshold value for determining that the partial discharge occurred was set to 10 pC, and a test voltage for the partial discharge was set to a maximum of 2.5 kVrms.

FIG. 10 (a) shows a test result of the power conversion device 100A. The test result shows that the second resin material 33 was filled in the upper part of the external terminal 15 of the semiconductor device 10 and the gap between the external terminal 15 and the board 20 without forming the void 36, so that no partial discharge occurred. Even at the maximum test voltage of 2.5 kVrms, no partial discharge occurred, and no dielectric breakdown occurred.

FIG. 10 (b) shows a test result of the power conversion device 100B. The test result shows that the second resin material 33 was filled in the upper part of the external terminal 15 of the semiconductor device 10 and the gap between the external terminal 15 and the board 20 without forming the void 36, so that no partial discharge occurred as in the power conversion device 100A. Even at the maximum test voltage of 2.5 kVrms, no partial discharge occurred, and no dielectric breakdown occurred.

FIG. 10 (c) shows a test result of the power conversion device 100C. The test result shows that discharge with the amount of charge of 1000 pC or more was detected at a voltage exceeding an applied voltage of 1.7 kVrms. Dielectric breakdown (flashover) also occurred between the external terminals 15. This is considered to be because the resin material 34 leaks from the gap between the semiconductor device 10 and the board 20 to expose the external terminals 15, so that creeping discharge occurs between the external terminals 15 to cause the dielectric breakdown.

FIG. 10 (d) shows a test result of the power conversion device 100D. The test result shows that partial discharge started to occur at a voltage exceeding an applied voltage of 1.7 kVrms, and exceeded the threshold value 10 pC for occurrence of partial discharge at 1.8 kVrms. After that, the voltage was increased to 2.0 kVrms, and the amount of charge discharged was about 40 pC. Even at the maximum test voltage of 2.5 kVrms, the amount of charge discharged was maintained at about 40 pC, and no dielectric breakdown occurred. This is considered to be because although no dielectric breakdown between the external terminals 15 occurred due to the upper part of the external terminal 15 that was covered with the resin material, the partial discharge occurred due to the void 36 formed under the external terminal 15. Although the dielectric breakdown does not certainly occur in a short-time insulation test, it is conceivable that a high voltage applied for a long period of time in actual use may cause the resin material or the insulation layer 21 of the board 20 to be subjected to partial discharge deterioration, thereby leading to dielectric breakdown in the worst case.

As described above, the power conversion devices 100A and 100B of the present invention are excellent in insulation reliability as compared with the power conversion devices 100C and 100D each using a conventional technique. Thus, the present invention enables the power conversion devices 100A and 100B to be further reduced in insulation distance between not only the external terminals 15 but also the wiring 22 of the board 20 and wiring. This configuration can contribute to reduction in main circuit inductance and miniaturization. The power semiconductor element 11 having a high withstand voltage may be applied to the semiconductor device 10 and the power conversion devices 100A and 100B.

### (FIG. 11)

The power conversion device 100A of the present invention is provided on its opposite surfaces with respective coolers 51, and an electrical insulative heat-dissipation agent 52 is provided between the power conversion device 100A and the cooler 51. This configuration enables the power conversion device 100A of the present invention to be mounted on a vehicle such as an EV or an HEV.

One embodiment of the present invention described above achieves operational effects below.

(1) The power conversion device 100A includes: the semiconductor device 10 including the semiconductor element 11 and the heat spreaders 12 and 13 that are sealed with the insulating resin 16, the external terminal 15 protruding from the insulating resin 16; and the circuit board 20 equipped with the semiconductor device 10 and including the power wiring layer 22 connected to the external terminal 15. The circuit board 20 includes the through-hole 24, and the semiconductor device 10 includes: the external terminal 15 and the power wiring layer 22 that are connected to each other on one surface of the circuit board 20; and the heat spreader 12 and the insulating resin 16 that are disposed partially passing through a through-hole 24 to protrude to the other surface of the circuit board 20. The semiconductor device 10 includes the flange part 16a facing or in contact with the one surface of the circuit board 20 and covering the opening edge of the through-hole 24 in the one surface of the circuit board 20. The first resin material 31 is filled into at least one of the gap 41 between the inner peripheral surface of the through-hole 24 and the insulating resin 16 of the semiconductor device 10 in the through-hole 24 and the gap between the one surface of the circuit board 20 and the flange part 16a. The one surface of the circuit board 20 is coated with a second resin material 33 to cover at least a connection part between the external terminal 15 and the power wiring layer 22. This configuration enables providing the power conversion device 100A in which ensuring of insulation reliability, improvement of heat dissipation, and miniaturization coexist with each other.

(2) The second resin material 33 has higher fluidity in a molten state than the first resin material 31. This configuration prevents resin from leaking from the gap between the board 20 and the flange part 16a of the semiconductor device 10.

(3) The gap between the insulating resin 16 and the through-hole 24 increases along the direction in which the insulating resin 16 protrudes to the other surface of the circuit board 20 through the through-hole 24. This configuration prevents resin from leaking from the gap between the board 20 and the flange part 16a of the semiconductor device 10.

(4) The heat spreader 12 includes the first surface 12a protruding to the other surface of the circuit board 20 and being disposed outside the other surface of the circuit board 20, and the first surface 12a is provided without the first resin material 31 or the second resin material 33. This configuration prevents the resin material from being formed on the heat spreader surface 12a.

(5) The first resin material 31 and the second resin material 33 each contain a filler, and the first resin material 31 has a larger content of the filler than the second resin material 33. Thus, even when the same resin material is used for the first resin material 31 and the second resin material 33, viscosity can be separated by the content of the filler.

(6) The circuit board 20 includes the resin frame 32 at the end part of the surface coated with the second resin material 33, and the first resin material 31 and the second resin material 33 each have a lower elasticity than a resin material used for forming the resin frame 32 and the insulating resin 16 of the semiconductor device 10. As a result, a crack to be formed between the resin materials 31 and 33, and the board 20, or between the resin materials 31 and 33, and the insulating resin 16 of the semiconductor device, can be suppressed.

The present invention is not limited to the above embodiments, and various modifications and other configurations can be combined without departing from the gist of the present invention. The present invention is also not limited to a configuration including every configuration described in each of the above embodiments, and includes a configuration in which a part of the configuration is deleted.

### REFERENCE SIGNS LIST

10 power semiconductor device
11 power semiconductor element
12 heat spreader (collector side of IGBT)
12a first surface
13 heat spreader (emitter side of IGBT)
14 bonding material
15 external terminal
16 insulating resin
16a flange part
20 printed circuit board
21 insulation layer of printed circuit board
22 circuit conductor (power wiring layer) of printed circuit board
23 through-hole
24 through-hole of printed circuit board
30 bonding material (solder)
31 first resin material
32 resin frame
33 second resin material
34 resin material (conventional)
35 leakage of resin material
36 unfilled part (void) of resin
41 gap between power semiconductor device and printed circuit board
41a gap close to first surface
41b gap close to board
51 cooler
52 electrical insulative heat-dissipation material
100 power conversion device using conventional technique
100A power conversion device of present invention
100B power conversion device of modification
100C power conversion device with first problem
100D power conversion device with second problem

1. A power conversion device comprising:
a semiconductor device including a semiconductor element and a heat spreader that are sealed with an insulating resin, and an external terminal that protrudes from the insulating resin; and
a circuit board equipped with the semiconductor device and including a power wiring layer connected to the external terminal,
wherein
the circuit board includes a through-hole,
the semiconductor device is disposed with the external terminal connected to the power wiring layer on one surface of the circuit board while a part of the heat spreader and the insulating resin of the semiconductor device protrude to another surface of the circuit board through the through-hole,
the semiconductor device includes a flange part facing or in contact with the one surface of the circuit board and covering an opening edge of the through-hole on the one surface of the circuit board,
at least one of a gap between an inner peripheral surface of the through-hole and the insulating resin of the semiconductor device in the through-hole and a gap between the one surface of the circuit board and the flange part is filled with a first resin material, and
the one surface of the circuit board is coated with a second resin material covering at least a connection part between the external terminal and the power wiring layer.

2. The power conversion device according to claim 1, wherein the second resin material has higher fluidity in a molten state than the first resin material.

3. The power conversion device according to claim 1, wherein a gap between the insulating resin and the through-hole increases along a direction in which the insulating resin protrudes to the other surface of the circuit board through the through-hole.

4. The power conversion device according to claim 1, wherein
the heat spreader includes a first surface protruding to the other surface of the circuit board and being disposed outside the other surface of the circuit board, and
the first surface is provided without the first resin material or the second resin material.

5. The power conversion device according to claim 1, wherein the first resin material and the second resin material each contain a filler, and the first resin material has a larger content of the filler than the second resin material.

6. The power conversion device according to claim 1, wherein
the circuit board includes a resin frame at an end part of the surface coated with the second resin material, and
the first resin material and the second resin material each have a lower elasticity than a resin material used for forming the resin frame and the insulating resin of the semiconductor device.
